(19) United States
(12) Patent Application Publication
(10) Pub. No.: US 2016/0061869 A1
(43) Pub. Date: Mar. 3, 2016

(54) RELIABLE PREDICTION OF ENERGY CONSUMPTION

(71) Applicant: Siemens Aktiengesellschaft, Munchen (DE)

(72) Inventors: Björn Dittmer, Nurnberg (DE); Arno Döbbeler, Herzogenaurach (DE); Ralf Engels, Heroldsbach (DE); Thomas Matschullat, Eckental (DE); Otto Schmid, Rottenbach (DE)

(73) Assignee: Siemens Aktiengesellschaft, Munchen (DE)

(21) Appl. No.: 14/842,436

(22) Filed: Sep. 1, 2015

(30) Foreign Application Priority Data
Sep. 2, 2014 (EP) 14183226.1

(51) Int. Cl. G01R 21/133; G01R 21/00

(52) U.S. Cl. CPC G01R 21/1338; G01R 21/007

(57) ABSTRACT

A basic materials industry facility having a type 1 electrical consumer with at least three working points that each have a respective expected power consumption is disclosed. The facility can also have type 2 or type 3 consumers, each having only two working points or a single expected power consumption assigned to them, respectively. Schedule diagrams for type 1 and 2 consumers define their working points as a function of time, taking into account technological criteria for the operation of the facility, and are continuously updated using actual energy consumption data in such a way that the expected total energy consumption between starting time point and a predefined end time point does not exceed a maximum permissible total energy consumption. Preferably the consumers are controlled so that the expected total energy consumption is brought close to the maximum permissible energy consumption.

### CROSS-REFERENCES TO RELATED APPLICATIONS

This application claims the priority of European Patent Application, Serial No. 14183226.1, filed Sep. 2, 2015, pursuant to 35 U.S.C. 119(a)-(d), the disclosure of which is incorporated herein by reference in its entirety as if fully set forth herein.

### BACKGROUND OF THE INVENTION

Large-scale industrial consumers of electrical energy often have special contractual arrangements with an energy supply organization that regulate their consumption of electrical energy. Contracts that determine the energy costs of an industrial large-scale consumer often have two components: One component of the contract is the price for the electrical energy actually consumed per billing unit, which is generally one year long, a calendar year for example. The other component is the price charged for making a stated maximum amount of electrical power available to be drawn over a defined period of time. The defined period of time is generally a range of minutes, between 5 minutes and one hour, for example, between 8 minutes and 30 minutes in particular. A typical period is 15 minutes. The greater the amount of energy that is made available, the higher the fee paid for it.

Also, if the large-scale industrial consumer draws more than the agreed maximum amount of electrical energy over the defined period of time, contractual penalties become due. For example, a higher tariff for each kilowatt hour consumed may be applied to the entire billing unit. Alternatively, or in addition, a previously defined penalty payment amount may become due. Thus, on cost grounds, the operators of industrial large-scale consumers endeavor to set the agreed maximum electrical energy that may be drawn as low as possible for the defined period of time, on the one hand, and not to exceed this amount of energy, on the other hand. Indeed it can happen that in certain load situations that the operators must selectively switch off individual consumers in order to prevent excessive consumption. This disrupts the planned production operation, and productivity drops.

One example of a large-scale industrial consumer is an electric steel works. An electric steel works typically has an arc furnace for melting down metal, a hearth oven for subsequent buffering and metallurgical treatment, and downstream aggregates such as a continuous casting facility and a rolling mill, for example, as important energy consumers. In addition, an electric steel works has “normal” consumers, such as for example fans, compressors, cooling units, electric lighting etc.

Measuring current energy consumption by a large-scale industrial consumer during such a contractual time period is known. Furthermore, when measuring the energy consumed so far in conjunction with a prediction about the future energy consumption, an assessment may then be made as to whether the agreed maximum electrical energy that may be drawn will be exceeded. When that is so, it is known to issue an alarm to operating staff, or to switched off selected consumers. However, this monitoring system has no knowledge of the actual process states of the individual consumers.

Detecting the energy consumed so far, within such a time period, defined in such a way, and assessing whether the agreed maximum electrical energy that may be drawn will be exceeded by reference to the energy consumed so far in conjunction with a prediction about the future energy consumption to is known. It is also possible to determine predicted load curves and feed those predicted load curve “schedules” into the monitoring system manually and to follow them fully automatically. Again, in that system, the monitoring system still has no knowledge of the actual process states of the individual consumers.

A method of assessing how long the electric arc furnace will continue in operation, using the quantity and nature of the material to be melted down, and then using that assessment to decide whether the agreed maximum electrical energy consumption will be exceeded is known. If so, the arc furnace will be switched to a lower operating level in which it draws less energy from the electrical supply network, according to that method. This approach is a step forward, in that it does anticipate an actual operating parameter of the industrial basic materials facility to a limited extent.

The present invention provides a particularly reliable option for achieving technologically-optimized operation of an industrial basic materials facility and assuring that it does not exceed the agreed maximum electrical energy that can be drawn within a defined period of time.

### SUMMARY OF THE INVENTION

The present invention provides an advantageous method of operation for an industrial basic materials facility that feeds a number of electrical consumers power over a supply network. At least one of the consumers is a type 1 consumer and the others are type 1 or type 2 or type 3. A number of working points are defined for each consumer of type 1 and of type 2. The number of working points in the case of consumers of type 1 is at least three, and for consumers of type 2 is exactly two.

An average power expected to be drawn from the supply network is assigned to type 3 consumers.

In accordance with the present invention, an instantaneous expected total energy consumption is determined for actual time points lying between a predefined starting time point and a predefined first end time point. The expected instantaneous total energy consumption for each type of consumer is the sum of the electrical energy actually drawn from the supply network by the consumers, from the starting time point up to the relevant actual time point, that is determined using measurement data, and an expected further energy consumption in the time period between the relevant actual time point and the first end time point. For each, the expected total energy consumption is compared with a maximum permissible total energy consumption.

The present invention is also provides a computer program having machine code that can be executed by a control device for an industrial basic materials facility, so that the execution of the machine code by the control device causes the control device to operate the industrial basic materials facility in accordance with a method of the present invention.

Furthermore, the present invention provides an industrial basic materials facility having a number of electrical consumers that are fed power from a supply network, that industrial basic materials facility having a control device in accordance with the present invention that is that is programmed to operate the industrial basic materials facility in accordance with the present invention.

In accordance with the invention, a schedule diagram that defines for each point in time within a time window the relevant working point for a given consumer is determined before the starting time point for each of the consumers of type 1 and type 2, taking into account technological criteria for the operation of the basic materials industry facility so that, in each case:
the time window extends at least from the starting time point to the first end time point,
to each of the working points, an expected power to be drawn from the supply network is assigned to the working point concerned,
the schedule diagrams for the consumers of type 1 and type 2 are determined in such a way that between the starting time point and the first end time point an initial total energy consumption is expected that does not exceed the maximum permissible total energy consumption,
the expected remaining energy consumption, from the relevant actual time point up to the first end time point, is given by the schedule diagrams for the type 1 and type 2 consumers and the average amounts of power expected to be drawn from the supply network by type 3 consumers,
when the relevant expected total energy consumption exceeds the maximum permissible energy consumption then, taking into account the technological criteria for the operation of the basic materials industry facility, the schedule diagram for at least one consumer of type 1 or of type 2 is varied, and/or at least one of the type 3 consumers is switched off, or the switching-on of at least one type 3 consumer is inhibited, so that the expected total energy consumption does not exceed the maximum permissible total energy consumption.

Thus there is not merely a passive prediction of the behavior of the basic materials industry facility, nor is there simply an updating of the behavior of the basic materials industry facility. Instead, the updating is effected, on the one hand, taking into account the technological criteria for the operation of the basic materials industry facility and, on the other hand, with a direct prediction of the effects that this will have on the energy consumption.

This achieves the effect, in particular, that the electrical consumption behavior of the type 1 and type 2 consumers can be predicted with greater accuracy, and it is therefore possible to appropriately optimize the schedule diagrams for these consumers.

It is possible that the schedule diagrams initially determined will only be changed if the relevant expected total energy consumption exceeds the maximum permissible total energy consumption. In one preferred embodiment, however, the expected maximum energy consumption is in each case compared not only with the maximum permissible energy consumption but, in addition, also with a minimum total energy consumption. It is then possible, if the relevant expected total energy consumption falls below the minimum total energy consumption, to vary the schedule diagram for at least one type 1 or type 2 consumer in such a way, taking into account the technological criteria for the operation of the basic materials industry facility, and/or to switch on at least one of the type 3 consumers, so that the expected total energy consumption comes closer to the maximum permissible total energy consumption.

Thus, the invention not only ensures that the maximum permissible total energy consumption not exceeded but, in addition, it also ensures that there is at least a tendency to fully utilized the maximum permissible energy consumption as much as possible.

As a rule, for the purpose of adhering to the maximum permissible total energy consumption, the schedule diagram for a type 1 consumer will be varied. In many cases—in particular if the maximum permissible total energy consumption will only be slightly exceeded—it can however be logical to switch off at least one of the type 3 consumers or to inhibit the switching-on of this type 3 consumer, taking into account the technological criteria for the operation of the basic materials industry facility. Examples of such consumers are, for example, compressors, cooling units, fans and other such items.

It is possible that the schedule diagrams only extend as far as the first end time point, or slightly beyond it. In one particularly preferred embodiment, however, provision is made, so that:
the schedule diagrams extend beyond the first end time point, at least up to a second end time point,
the difference in time between the second end time point and the first time end point is equal to the difference in time between the first end time point and the starting time point, and
in the context of the determination and varying of the schedule diagrams, a further expected energy consumption that relates to the time period between the first end time point and the second end time point is also taken into account.

Thus, it is possible to jointly optimize the schedule diagrams across the current defined time period and at least the next one. Furthermore, a corresponding approach can also be extended to time periods that follow that next defined time period.

In certain operating states of the basic materials industry facility it is possible that, for higher-level reasons, certain type 1 or type 2 consumers must of necessity continue to be operated. This can also apply in the case that the expected total energy consumption concerned exceeds the maximum permissible total energy consumption. Thus, there may be a situation in which the relevant expected total energy consumption exceeds the maximum permissible total energy consumption but, taking into consideration of the technological criteria for the operation of the basic materials industry facility, it is not possible to vary the schedule diagram for that at least one type 1 or type 2 consumer in such a way that, after that variation in the schedule diagram, the expected total energy consumption does not exceed the maximum permissible total energy consumption. Depending on the situation in the individual case it is therefore possible that exceeding of the maximum permissible total energy consumption must be accepted in that case.

Preferably, in the case that the energy actually consumed between the starting time point and the first end time point exceeds the maximum permissible total energy consumption, the maximum permissible total energy consumption then increases at least for some time periods following on from the first end time point. This cannot, of course, undo having exceeded the previous maximum permissible total energy consumption. In many cases, however, insofar as concerns the fee to be paid to the energy supply company, it is irrelevant whether the maximum permissible total energy consumption is exceeded only once or several times.

In the situation that the maximum permissible total energy consumption has been exceeded once, the schedule diagrams for consumers of type 1 and of type 2 can be optimized for the subsequent time periods irrespective of whether the previous maximum permissible total energy consumption is again exceeded or not. Using this approach it is possible in some circumstances to determine better ways of operating, from the point of view of optimizing the operation of the basic materials industry facility—disregarding the increased energy costs that are now inescapable within a predetermined subsequent time period.

It is possible to vary the schedule diagrams irrespective of the operating state of the consumers at that instant. Preferably, however, each of the type 1 and of type 2 consumers will be assigned, either statically or dynamically, a high or a low priority level. This means it is possible to give preference to varying the schedule diagrams assigned to the type 1 and of type 2 consumers that have a low priority level at that instant when varying the schedule diagrams. Thus it is possible to specify which schedule diagrams should preferentially be varied, and which schedule diagrams should only be varied if variation of schedule diagrams that are preferentially varied does not suffice. Furthermore, a corresponding approach can be extended to more than two priority levels if necessary.

In one particularly preferred embodiment of the method of operation, the amounts of power actually being drawn from the supply network by the consumers of type 1 and of type 2 are detected, and furthermore. the amounts of power expected to be drawn from the supply network that are assigned to the current working points are updated using the amounts of power actually being drawn from the supply network. By this means, over the course of time, an ever better prediction is obtained for the expected total energy consumption.

In an analogous way, it is possible that the amounts of power actually drawn from the supply network by consumers of type 3 are detected, and that the amounts of power expected to be drawn from the supply network that are assigned to the consumers of type 3 are updated using the amounts of power actually being drawn from the supply network.

The basic materials industry facility can be structured for as required for operation in accordance with a particular industrial environment. For example, the basic materials industry facility may be constructed as an electric steel works, in particular, one that has an arc furnace and/or a hearth oven as electrical consumers of type 1. Furthermore, these two furnaces—that is the facility's electrical consumers of type 1—have electrodes that are fed from the supply network. Control of the working point of these consumers, in particular, preferably incorporates height setting for the electrodes above the bath surface for the arc furnace or hearth oven. This approach has the particular advantage that power drawn from the supply network can be smoothly and continuously adjusted by setting that height, in contrast to switching from one tap to another on a transformer assigned to the electrodes, for example. In contrast, that type of switching can only be effected in steps.

It is possible that the maximum permissible total energy consumption is a constant. Alternatively, it is possible that the maximum permissible energy consumption is varied as a function of the network load on the electrical supply network. It is furthermore possible to report expected energy consumption that has been determined to a higher-level system, enabling the higher-level system to utilize the energy not required for other purposes, for example. Alternatively or in addition, the maximum permissible energy consumption can be adjusted for later time periods.

A control device of a basic materials industry facility advantageously executes a machine code computer program in accordance with the invention. Execution of the computer program causes the control device to operate the basic materials industry facility in accordance with the method of the invention.

A computer network in a basic materials industry facility advantageously executes a computer program in accordance with the invention. Execution of the computer program causes the control device to operate the basic materials industry facility in accordance with the method of the invention.

A basic materials industry facility is advantageously operated in accordance with the method of the invention.

In accordance with the invention, the control device for a basic materials industry facility of the type mentioned in the introduction is constructed in accordance with the invention and operates the basic materials industry facility in accordance with a method of operation in accordance with the invention.

The basic materials industry facility can, in particular, be constructed as an electric steel works and have an arc furnace and/or a hearth oven as an electrical consumer of type 1.

### BRIEF DESCRIPTION OF THE DRAWINGS

Other features and advantages of the present invention will be more readily apparent upon reading the following description of currently preferred exemplified embodiments of the invention with reference to the accompanying drawing, in which:

FIG. 1 shows a controller for a facility in accordance with the invention;

FIG. 2 is a data field for the consumers shown in FIG. 1;

FIG. 3 shows an exemplary embodiment of a basic materials industry facility having the consumers shown in FIG. 1;

FIG. 4 is a power demand diagram for the facility of FIG. 3;

FIG. 5 is a power scheduling flow chart in accordance with the invention;

FIGS. 6 to 8 are exemplary power schedule diagrams;

FIGS. 9 to 11 are flow charts related to the flow chart shown in FIG. 5;

FIG. 12 is a data field for consumers shown in FIG. 1 with priority values; and

FIGS. 13 to 14 are flow charts related to the flow chart shown in FIG. 5.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

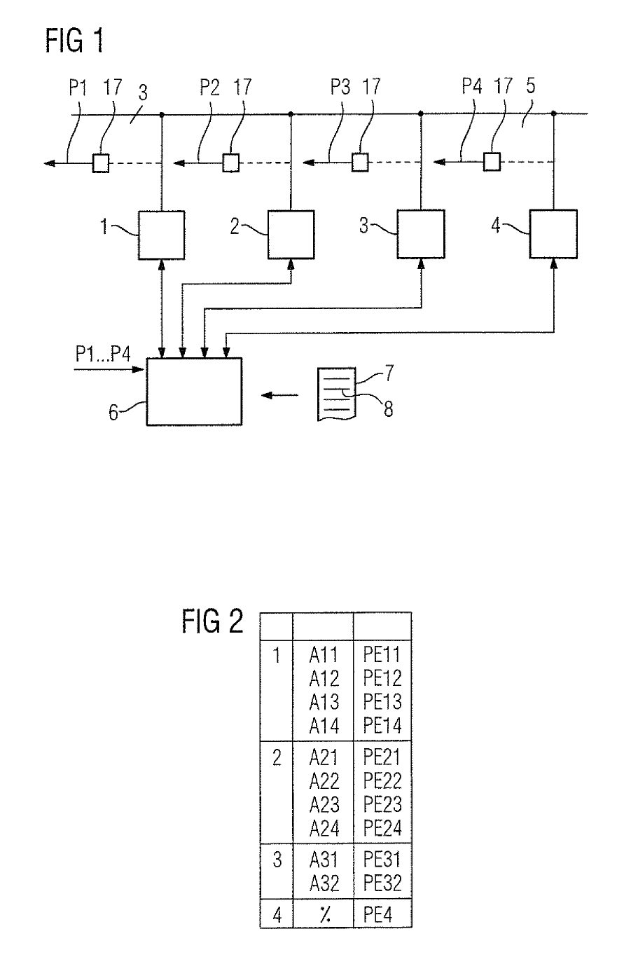

In a basic materials industry facility having a number of electrical consumers 1 to 4 that are fed from an electrical supply network 5, four such consumers 1 to 4 are shown in FIG. 1. The number of electrical consumers 1 to 4 can however also be smaller, in rare cases, or larger, in general.

Regardless of the type of basic materials industry facility there is always a type 1 electrical consume in such facilities, the electrical consumer 1 in FIG. 1. Other consumers 2 to 4 may be present, as required, and if they are present, they can also be of type 1. Alternatively, they can be of a type 2 or of a type 3. In the present case it is assumed that the consumer 2 is also a type 1 consumer. The consumer 3 is a type 2 consumer and the consumer 4 is a type 3 consumer. However, there could equally well be a different split. As already mentioned, it is also possible that more than these four consumers 1 to 4 are present.

The consumers 1, 2, are of type 1, as shown in FIG. 2, and a number of working points Aij (i=an index for the consumer concerned, j=an index for the working point concerned) are defined for each of them in a control device 6 for the basic materials industry facility, The number of working points Aij is at least three. Often, the number of working points Aij for some consumers 1, 2, is substantially greater than 3, that is, greater than 5, greater than 8, greater than 10 etc., for example. The number of working points Aij can vary between of type 1 consumers 1, 2.

The appropriate settings for an electrical consumer 1, 2, of type 1, and a power PEij, are stored in the control device 6 for each working point Aij, The power PEij is the amount of power that is expected to be drawn from the electrical supply network 5 at the working point Aij of the corresponding consumer 1, 2, of type 1. The amounts of power PEij can, insofar as is necessary, can be broken down into reactive, real and/or complex power. The corresponding amounts of power PEij are assigned to the relevant working points. A respective expected amount of power PEij assigned to at least two of the working points Aij is non-zero. It is possible that the expected amounts of power PEij assigned to two different working points Aij are the same. If this is the case, this situation is purely due to chance, not to the system. In any case, in such a situation, the settings for the working points Aij of the relevant electrical consumers 1, 2 of type 1 will differ from each other.

Consumers 3 of type 2 are characterized in a similar way to consumers 1, 2, of type 1. The critical difference is that the number of working points Aij for the consumer 3 of type 2 will be exactly two. So the index j can only have the values 1 or 2. A corresponding expected amount of power PEij, which is non-zero, is assigned to at least one of the working points Aij.

In the case of consumers 4 of type 3, no breakdown according to working point is stored in the control device 6. For consumers 4 of type 3, the control device 6 stores only an average value for the power PEi (i=a consumer index) drawn from the supply network 5 by the consumer 4, that is averaged over time.

In practice, there are often only type 1 consumers and type 3 consumers present, that is, no consumers of type 2. However the presence of consumers of type 2 is not completely excluded.

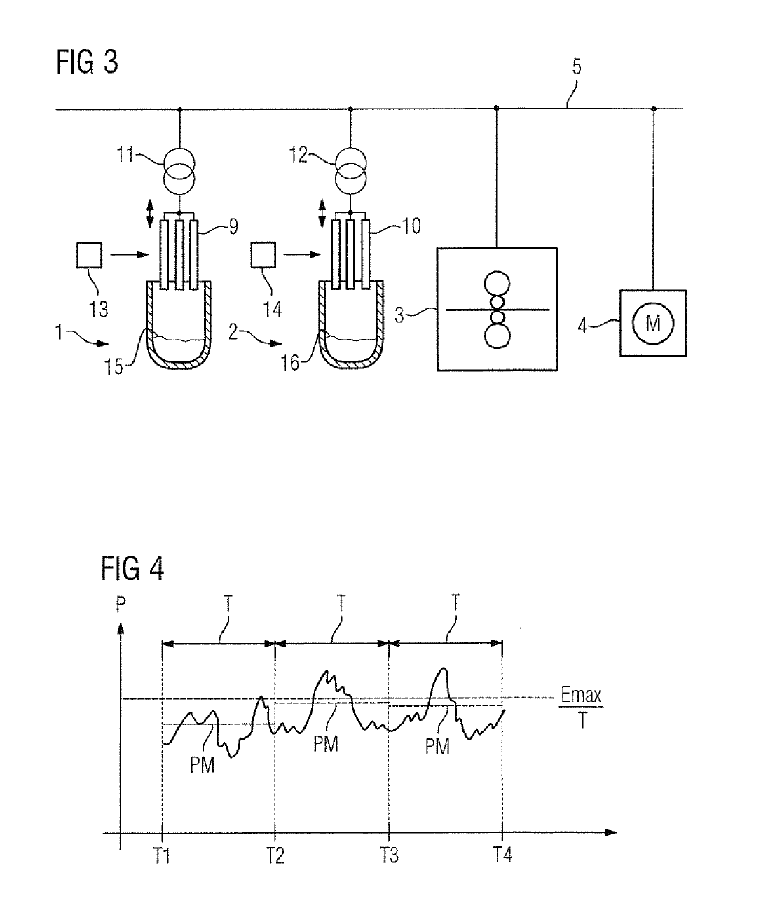

In FIG. 1, the control device 6 according to the invention is programmed using a computer program 7. The computer program 7 incorporates machine code 8 executed by the control device 6. The execution of the machine code 8 by the control device 6 causes the control device 6 to operate the basic materials industry facility in accordance with a method of operation explained below with reference to FIG. 3.

In the example shown in FIG. 3, the basic materials industry facility is an electric steel works. In this case, the consumers 1, 2, of type 1 can be an arc furnace and/or a hearth oven, for example. In general, both consumers 1, 2, will be present, that is, both the arc furnace 1 and also the hearth oven 2. Further consumers 3, 4, in the electric steel works can be classified as type 2 or type 3 consumers, as required. For example, a rolling mill can be classified as a consumer of type 2. Other consumers in the electric steel works, compressors, cooling units, and pumps, for example, can be classified as type 3 consumers. The furnaces 1, 2, are the primary consumers in the electric steel works, consumers that account for the largest proportion of the total consumption of energy from the supply network 5 in the electric steel works, by far. This applies particularly for the arc furnace 1. Furthermore, the power consumption of the furnaces 1, 2 can be rapidly modified. They are thus exceptionally suited to be controlling elements in a regulation system for adherence to the maximum permissible total energy consumption value Emax.

The furnaces 1, 2, have electrodes 9, 10, that are generally fed from the supply network 5 through an associated transformer 11, 12. Usually, each of the transformers 11, 12, has several taps. In these cases, the relevant working point Aij for the furnace 1, 2, in particular, includes details of the taps from that the electrodes 9, 10, are fed from the supply network 5. If necessary, some other type of voltage setting is possible. In this case, the nature of this voltage setting is a component of the applicable working point Aij.

In general there will be additional equipment 13, 14, that affects the height that is set for the electrodes 9, 10, above the applicable bath surface 15, 16, of the furnace 1, 2. In particular, the working points Aij of the respective furnace 1, 2, can also include details of this height setting, directly or indirectly. For example, the working points Aij for the furnace 1, 2, can include a specification for height-setting actuation or regulatory equipment. This specification can be issued in the form of an impedance setpoint, a current setpoint or a resistance setpoint, for example. Other settings are also conceivable. So, for example, a choke that is connected upstream from many furnaces 1, 2, is arranged on the primary side of the transformer 11, 12, that has several taps. In this case, the working point Aij also includes details of which tap of the choke is used.

The above embodiments use three-phase AC arc furnaces. However, analogous approaches, in particular approaches using different working points Aij, are also possible for other furnaces, DC arc furnaces, for example.

The working points Aij for the furnaces 1, 2, will often include other details, such as the transformer taps, as already mentioned, the type of metal or steel used, the quantity of metal that is to be melted down, the time of day, time of year and many other details.

As can be seen in FIG. 4, time points T1, T2, etc. are known to the control device 6. These time points T1, T2, are equidistant. In each case they cover a time period having a duration T. FIG. 4 shows that when the actual power consumption P from the supply network 5 for the basic materials industry facility is plotted, the power consumption P varies as a function of time.

The power consumption P can be adjusted within certain limits by varying the operation of the basic materials industry facility. In accordance with the present invention, the basic materials industry facility operates in such a way that in each of the time periods an actual energy consumption E1, that is, the average power PM consumed in that time period multiplied by the duration time T, does not exceed an agreed maximum energy consumption Emax, that is, the maximum permissible total energy consumption Emax.

The time period between the time points T1 and T2 is considered below, purely by way of example. However, the same approach is also adopted in respect of the other time periods, that is, for the time periods bounded by the time points T2 and T3 or T4 and T5, for example.

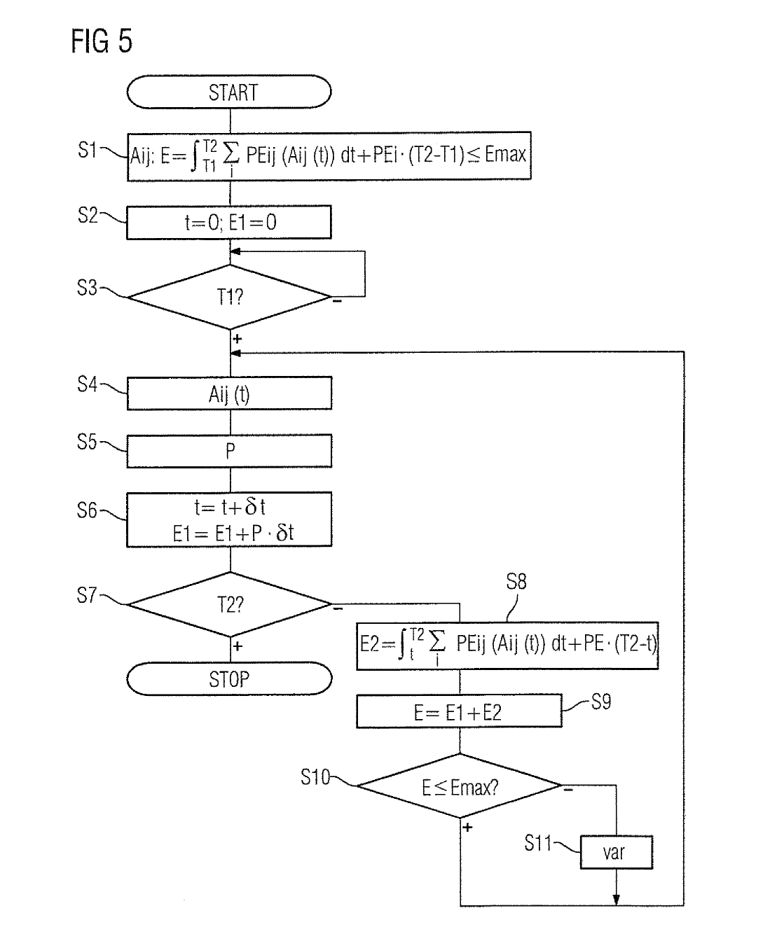

In FIG. 5, in order to ensure that the actual energy consumption in the time period bounded by the time points T1 and T2 does not exceed the maximum permissible total energy consumption Emax, the control device 6 starts in step S1 by defining a schedule diagram for each of the consumers 1, 2 of type 1 and—if there are any—for the consumers 3 of type 2. For example, the control device 6 can select or modify predefined schedule diagrams. The predefined schedule diagrams may, as alternatives, be stored in the control device 6 or in another control device to which the control device 6 has access.

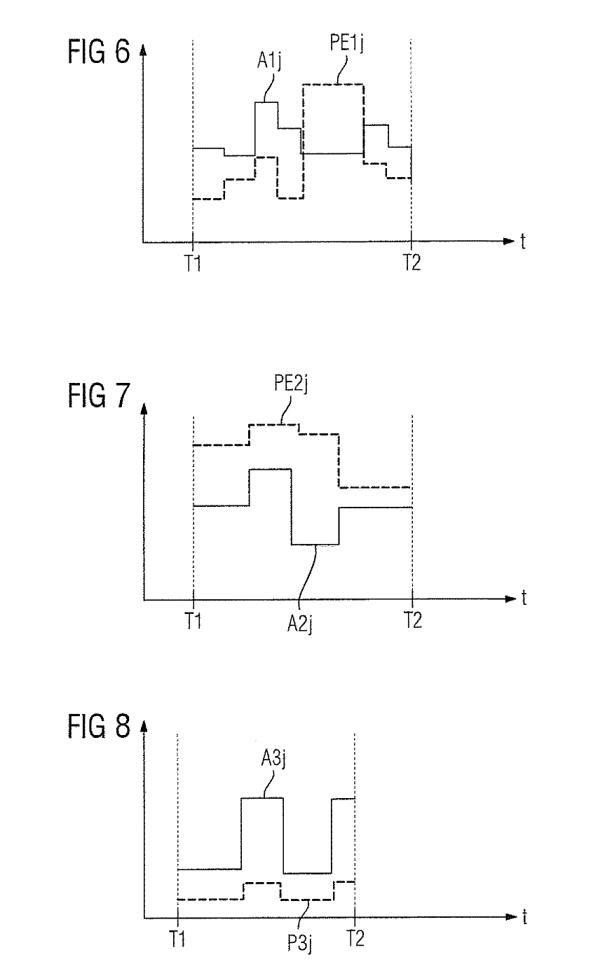

Purely by way of example—FIGS. 6 to 8 show possible schedule diagrams for the consumers 1 to 3. As shown in FIGS. 6 to 8, the schedule diagrams extend over a time window which, for its part, extends at least from time point T1 to time point T2. It is possible that the schedule diagram starts even before time point T1 and/or ends after time point T2. Extending over the period from time point T1 to time point T2 is thus a minimum requirement. In the present instance, the schedule diagrams also include those phases of operation of the consumers 1, 2, 3, of types 1 and 2 during which the consumers 1, 2, 3, concerned draw no energy from the electrical supply network 5.

In FIGS. 6 to 8, each schedule diagram shows the relevant working point Aij for each consumer 1, 2, 3, at each point in time t within the applicable time window. When determining the schedule diagram in step S1, account is taken of technological criteria for the operation of the basic materials industry facility. For example, a rule-based expert system—which is known per se—can be used to define the working points Aij for the consumers 1, 2, of type 1 in a way that is appropriate for the process technology and, if necessary, also for the consumer 3 of type 2. As shown in the step S1, the definition of the schedule diagrams for the consumers 1, 2, 3, of type 1 and type 2 is effected in such a way that the total energy consumption E which is expected does not exceed the maximum permissible total energy consumption, taking into account of course the technological criteria for the operation of the basic materials industry facility.

The step S1 is executed before the time point T1 insofar as it relates to the determination of the working point Aij as such, as is known. However, in accordance with the invention, even at this point in time a determination is made of the expected total energy consumption E, as obtained by reference to the schedule diagrams and their associated amounts of power PEij for the consumers 1, 2, 3. of type 1 and 2, together with the average amounts of power PEi for the consumers 4 of type 3 as part of the step S1.

In step S2, the control device 6 then sets the time point t and an actual energy consumption value E1 each to the value 0. Thereafter, in step S3 the control device 6 waits until the time point T1 is reached. From the time point T1, the control device 6 moves on to step S4.

In step S4, the control device 6 actuates the basic materials industry facility in accordance with the parameters that apply at that time point. In particular, actuation of the consumers 1, 2, 3, of type 1 and of type 2 is effected in accordance with the working point Aij specified for the relevant time point t by the applicable schedule diagram for the respective consumer 1, 2, 3.

In step S5, the control device 6 detects the actual amount of power P consumed from the electrical supply network 5. As part of the approach shown in FIG. 5 it is sufficient, in principle, if only the actual power consumption P is detected, as such. What is critical is that the actual power consumption P is determined on the basis of measured data. So what is concerned is an actual, measured magnitude, not a computationally determined magnitude. Preferably, indeed, the relevant power consumption Pi (index i for the consumer 1, 2, 3, of type 1 or type 2) will be detected separately at least for each of the consumers 1, 2, 3, of type 1 and of type 2 and, in addition, at least the total power consumption P4 for the consumers of type 3. Nevertheless, in this case too, the total power P is determined from the amounts of power detected by measurement. Furthermore, insofar as is necessary, a correction can be applied to the measured values detected. This can be necessary, for example, in order to compensate for power losses that arise between the measurement point and the supply terminals to the electrical supply network 5. This, again, does not alter the fact that the total power P is determined by the measurement of detected amounts of power.

In step S6, control device 6 increases the actual time point t by a time step of width δt. In addition, in step S6 the control device 6 increases the actual energy consumption E1 by the instantaneous energy consumption, given by the product of the actual power consumption P and the width of the time step δt. In general, the width of the time step δt lies in a range less than 1 second, often less than 100 ms.

In step S7, the control device 6 checks whether the time point T2 has been reached. If so, the operation in accordance with the invention is finished, insofar as it relates to the time period under consideration that is the time period bounded by the time points T1 and T2. Otherwise, the control device 6 moves on to a step S8.

In step S8, the control device 6 determines an expected remaining energy consumption E2. In accordance with step S8, this expected remaining energy consumption E2 is given, by the schedule diagrams for the consumers 1, 2, 3, of type 1 and type 2, or by the corresponding expected amounts of power PEij, and also the average expected amounts of power PEi for the consumers of type 3. This is calculated from the relevant actual time point t up to the time point T2.

In a step S9, the control device 6 then determines an expected total energy consumption E. This expected total energy consumption E is given by the sum of the actual energy consumption E1 up to the current time point t and the remaining energy consumption E2 expected at this point in time t.

In a step S10, the control device 6 compares the expected total energy consumption E, determined in step S9, with the maximum permissible total energy consumption Emax. If the expected total energy consumption E does not exceed the maximum permissible total energy consumption Emax, the control device 6 returns to step S4. Otherwise, the control device 6 moves on to a step S11.

In step S11, the control device 6 can vary the schedule diagram for at least one of the consumers 1, 2 of type 1. If at least one consumer 3 of type 2 is present, the control device 6 can alternatively or additionally, as part of step S11, vary the schedule diagram for that consumer 3. In step S11 variation of the schedule diagram, or diagrams, will be effected in a way analogous to step S1, by taking into account the technological criteria for the operation of the basic materials industry facility. This variation is effected in a way such that, after the variation of the schedule diagram or schedule diagrams, as applicable, the expected total energy consumption E does not exceed the maximum permissible total energy consumption Emax.

This check at S11 is immediately possible as part of the inventive approach, because corresponding amounts of power PEij are assigned to individual working points Aij. Thus, when the working points Aij are specified, the corresponding amounts of power PEij are also known. In particular, the variation of the working points Aij can include a change to the time points for switching on, for switching off, for switching stages and changes for many other such items.

Furthermore, in addition to varying the schedule diagrams, and also as an alternative to doing so in exceptional cases taking into account the technological criteria for the operation of the basic materials industry facility, it is possible that the control device 6 switches off at least one of the consumers 4 of type 3 or at least inhibits the switching on of at least one of the consumers 4 of type 3. By this means too, it is possible to achieve the result that the expected total energy consumption E does not exceed the maximum permissible energy consumption Emax. For example, if the maximum permissible energy consumption Emax is only slightly exceeded, the consumers 4 of type 3 that are candidates for this change are, in particular, units that only operate from time to time, for system reasons. Purely by way of example, it is possible that these are compressed air compressors, hydraulic pumps, cooling units, and many other such items.

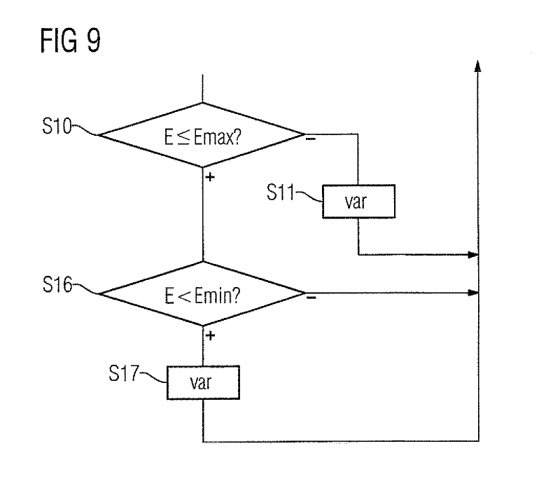

The scheduling approach shown in FIG. 5 can be structured in various ways. Thus it is possible, as shown in FIG. 9 for example, to provide additional steps S16 and S17 in the YES branch of step S10.

In step S16, the control device 6 compares the expected total energy consumption E with a minimum total energy consumption Emin. This minimum total energy consumption Emin is, of course, smaller than the maximum permissible energy consumption Emax. For example, the minimum total energy consumption Emin can be defined as a (relatively high) percentage of the maximum permissible energy consumption Emax, for example a value between 90% and 99%. Alternatively, the minimum total energy consumption Emin can be defined by a relatively small absolute difference from the maximum permissible energy consumption Emax.

If the expected total energy consumption E falls below the minimum total energy consumption Emin, the control device 6 moves on to step S17. In step S17, the control device 6 varies—in an analogous way to that in step S11 in FIG. 5—the schedule diagram for at least one consumer 1, 2, 3 of type 1 or of type 2, taking into account the technological criteria for the operation of the basic materials industry facility. Here again—although not as a mandatory matter, but preferably—the schedule diagram for at least one consumer of type 1 is varied. Alternatively or additionally, in step S17 at least one consumer 4 of type 3 can be switched on. The objective of step S17 is that the expected total energy consumption E after execution of step S17 should be brought close to the maximum permissible total energy consumption Emax.

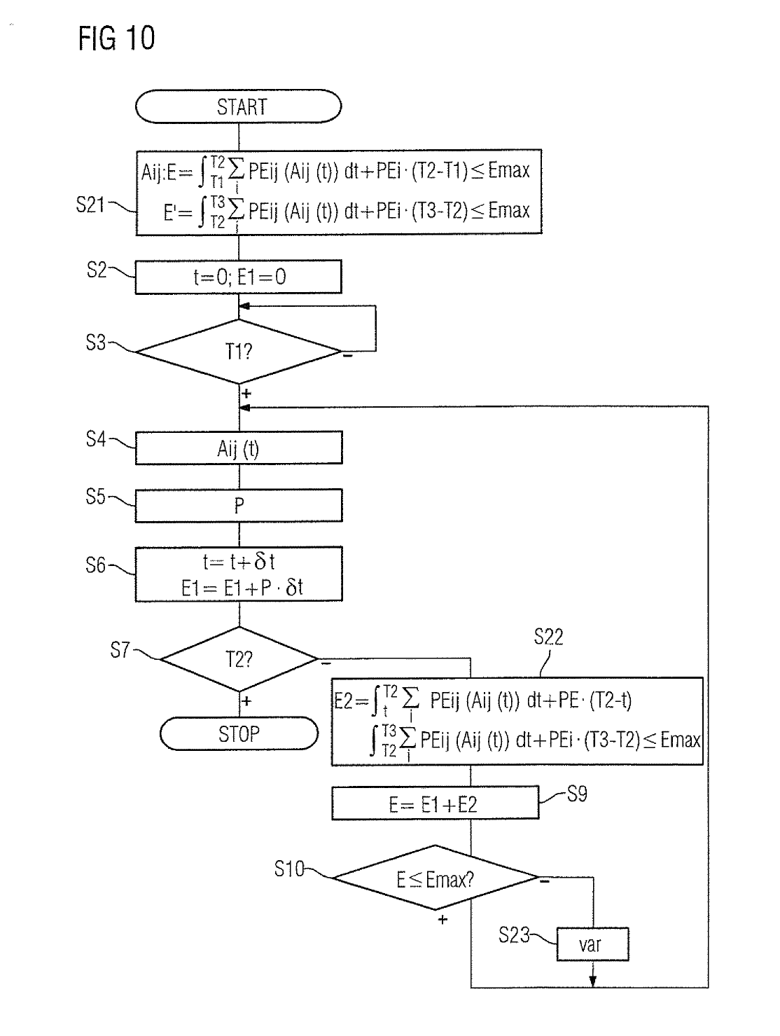

As already mentioned, at the point in time when the step S1 in FIG. 5 is executed, the schedule diagrams will extend at least from the time point T1 to the time point T2. However, it is possible that the schedule diagrams extend further, for example up to the time point T3, up to the time point T4, or even further. In that case, the schedule diagrams, in a way similar to predictive control, will be used not only for an individual time period T, but for several time periods T. In this case it is possible to replace the steps S1 and S11 with steps S21 and S22, as shown in FIG. 10.

In step S21, as already explained in conjunction with steps S1 and S11 of FIG. 5, as part of the determination of the schedule diagrams for the consumers 1, 2, of type 1, and also the consumers 3 of type 2, if appropriate, the expected energy consumption E for the period between the time points T1 and T2 is determined, on the one hand. However, on the other hand, a further expected energy consumption E′ is also determined in an analogous way. This energy consumption E′ relates to the time period between the time points T2 and T3. It would also be possible, if necessary, to determine further energy consumptions relating to even later time periods in an analogous way. FIG. 10 shows the maximum permissible total energy consumption Emax for the time period between the time points T2 and T3 as being equal to the maximum permissible total energy consumption Emax for the time period between the time points T1 and T2. However, this is not absolutely necessary. Alternatively it could have another value.

As part of step S21, in determining the schedule diagrams, for the period between the time T1 and T2 for the consumers 1, 2, of type 1 and, if necessary, also for the consumers 3 of type 2, the effects that the schedule diagrams adopted for the time period between the time points T1 and T2 will also have to be taken account of, because of the technological criteria that must be taken into account in the operation of the basic materials industry facility on the schedule diagrams for the consumers 1, 2, 3, of type 1 and type 2 for the time period between the time points T2 and T3. It is thereby possible, for example, that within certain limits the power requirements for the individual consumers 1, 2, 3, of type 1 and type 2 can be moved backward and forward between the two time periods bounded by the time point T2 and, if necessary, also further time periods bounded in each case by two of the predefined time points T3, T4, etc. The procedure in step S22 is also completely analogous.

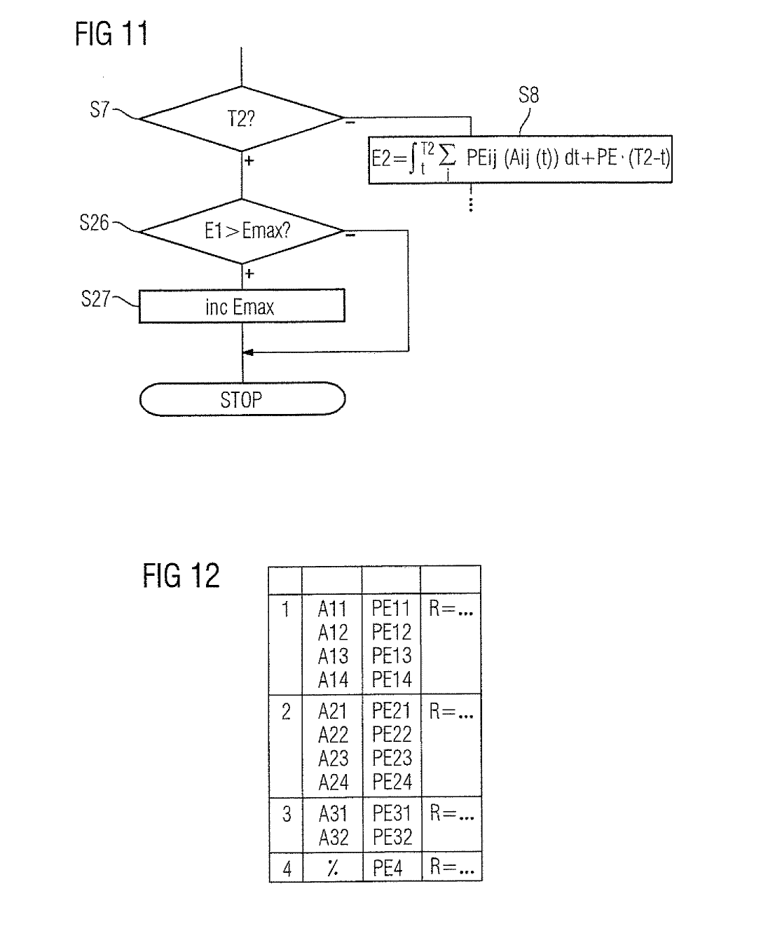

It is also possible, as shown in FIG. 11, to provide additional steps S26 and S27 in the YES branch of step S7 in FIG. 3. In step S26, the control device 6 compares the energy E1 actually consumed between the time points T1 and T2 with the maximum permissible total energy consumption Emax. In particular, the control device 6 checks whether the energy E1 actually consumed exceeds the maximum permissible total energy consumption Emax. In general, this will not be the case. In this situation, no further measures will be initiated.

It is, however, possible that the energy E1 actually consumed exceeds maximum permissible total energy consumption Emax. A situation of this type can arise, for example, if higher-level technological conditions make it impossible to reduce the energy consumed from the supply network 5. For example, in the case of an electrical steel works, the feeding of a continuous casting facility with liquid metal takes priority over adherence to the maximum permissible total energy consumption Emax. So, if there is a risk that the continuous casting facility will run empty, an operational disruption of this type must be counteracted and a concomitant overshoot of the maximum permissible total energy consumption Emax must be accepted.

If the control device 6 determines in step S26 that such an excess will occur, it moves on to step S27. In step S27, the control device 6 increases the maximum permissible total energy consumption Emax, at least for the time periods following the time point T2. A reason for this measure can be that, because of a one-off excess in the time period between the time points T1 and T2, a contractual penalty has become due, the level of which is however independent of whether the maximum permissible total energy consumption Emax applicable for the time period between the time points T1 and T2 is again exceeded in the subsequent time periods for example in the time period between the time points T3 and T4. This will be explained in more detail below by reference to an example.

Assume that, in a time period T, of 15 minutes, for example, the basic materials industry facility may draw from the supply network 5 a maximum of 25 MWh. If this value is exceeded, a contractual penalty of [symbol] 10,000.00 becomes due. Furthermore, the total amount of energy consumed during the current month will be billed with a surcharge of 100%. A higher contractual penalty and/or a higher tariff would become due if a value of 30 MWh were exceeded.

In a situation of this type, the maximum permissible energy consumption. Emax is set at a value of 25 MWh. It can also be set at a slightly smaller value, for example 24 MWh, in order to provide a safety buffer. If, in this situation, on the 5^{th} day of the month an actual energy consumption E1 in one of the time periods is—regardless of the reason—25.3 MWh, the contractual penalty is invoked, and double the tariff is payable for the entire month. This applies regardless of whether or not the limit of 25 MWh is again exceeded in subsequent time periods up to and including the last one of the month. Larger penalty payments will then become due again only if the limit of 30 MWh is exceeded. In such a situation it is therefore possible to raise the maximum permissible energy consumption Emax for the remainder of the month from 25 MWh to 30 MWh with no negative consequences. If necessary, an increase to a value between 25 MWh and 30 MWh can be made, for example 27.5 MWh and 28 MWh, in order to have a safety buffer—this time a larger one. It is furthermore possible to take into account this higher value even in the time period T between the time points T2 and T3, because on reaching the time point T2 it is virtually immediately available.

As part of an initial determination of the schedule diagrams—c.f. step S1 in FIG. 5—and also as part of the variation of the schedule diagrams—c.f. step S11 in FIG. 5 and the steps S17 and S22 in FIGS. 9 and 10—the schedule diagrams are defined or varied, as applicable, in a particular manner. It is possible that priority levels R are assigned to the consumers 1, 2, of type 1, and possibly also the consumers 3 of type 2, as illustrated in FIG. 12. The priority levels R concerned can at least take a low value and a high value (R=1 or R=2). If necessary, there can be finer gradations, for example R=1 to R=4.

In this case it is possible, when the schedule diagrams are being varied, to give preference to varying the schedule diagrams assigned to those consumers 1, 2 of type 1, and if necessary also to the consumers 3 of type 2, to which a low priority level R=1 is assigned. Only if it is no longer possible to achieve the desired objective—adherence to the maximum permissible total energy consumption Emax, for example—by varying solely the schedule diagrams for the consumers 1, 2, 3 with a lower priority level R, will schedule diagrams for consumers 1, 2, 3, having a higher or the next higher priority level R, as applicable, also be varied.

It is possible that the priority levels R for the consumers 1, 2, and if necessary also 3, are assigned statically. Alternatively, the priority levels R can be assigned dynamically. For example, in the case of an electric steel works there can temporarily be states of the arc furnace 1, the hearth oven 2 or other units—including possibly units that are not electrically operated—on the basis of which the variation of a schedule diagram for a particular electrical consumer 1, 2, 3,—for example the hearth furnace 2—would have exceptionally negative consequences. In a situation of this type, the hearth furnace 2 would be temporarily assigned the highest priority level R, for example, if there are two priority levels the value R=2, or in the case of four priority levels the value R=4. At a later point in time the priority level R assigned to the hearth oven 2 can, in such a case, be reset to the value R=1 or, in the case of four priority levels R, for example to a value R=1 or a value R=2.

As already mentioned, it is in principle sufficient, in the context of the inventive method of operation, to detect metrologically the actual power consumption P of the basic materials industry facility in its entirety. Preferably, however, measurement equipment 17 will be provided in each case, as shown in FIG. 1, at least for each of the individual consumers 1, 2, of type 1 and also—if there are any—for the individual consumers 3 of type 2, by means of which the power consumption Pi (i=index of the consumer 1, 2, 3 concerned) is individually detected for the consumer 1, 2, 3. Furthermore, either the total actual power consumption P of the basic materials industry facility in its entirety, or the remaining power consumption P4 of the consumers 4 of type 3 in its entirety will be detected. If necessary, the actual power consumed can also be detected individually for consumers 4 of type 3.

Because, at any point in time, the relationship

$${\sum }_{i} Pi + P 4 = P$$

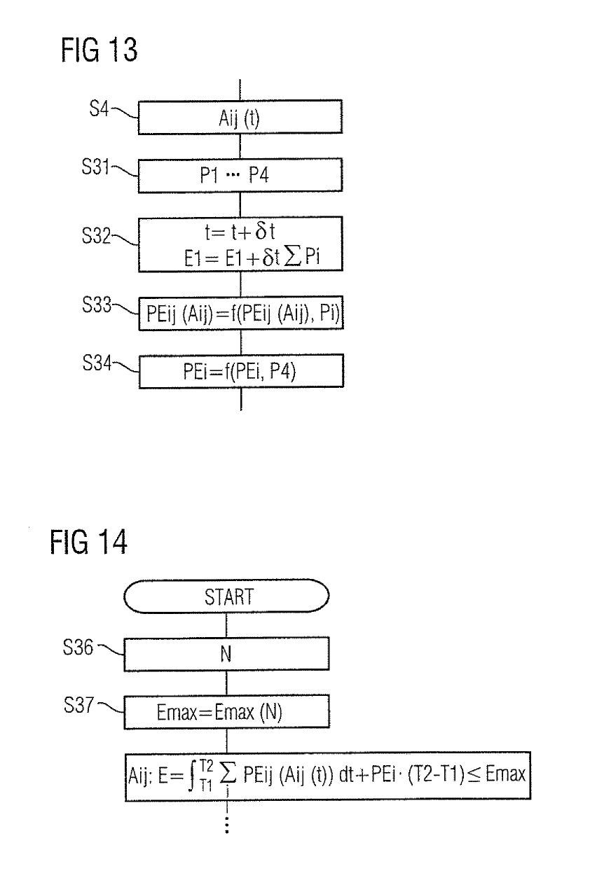

is true, it is possible to determine in its entirety the power consumption P, from the detected power consumptions Pi of the consumers 1, 2, 3 of types 1 and 2 and the remaining power consumption P4, or to determine the remaining power consumption P4 from the detected power consumptions Pi of the consumers 1, 2, 3 of types 1 and 2 and the total power consumption P of the basic materials industry facility. In this case, the approach of FIG. 5 will preferably be modified as shown in FIG. 13.

In FIG. 13, the steps S5 and S6 in FIG. 5 are replaced by steps S31 and S32. Furthermore, there are additional steps S33 and S34. In step S31, the control device 6 detects metrologically the actual power consumptions Pi from the supply network 5 for the consumers 1, 2, 3 of type 1 and type 2 and—individually, in their entirety or in groups—the power consumption P4 from the supply network 5 for the consumers 4 of type 3. In step S32, analogous to step S6, the control device 6 determines the actual energy consumption E1 up to the present. In step S33, the control device 6 updates, by reference to the relevant actual power Pi drawn from the supply network, the expected amount of power PEij assigned to the instantaneous working point Aij for the consumers 1, 2, 3, of type 1 or type 2, as applicable. In the step S34, the control device 6 updates in an analogous way the expected amounts of power PEi assigned to the consumers 4 of type 3—individually, in its entirety or in groups, depending on how the power consumption P4 is detected.

It is possible that the maximum permissible total energy consumption Emax is permanently set, at least for the time when it has not been updated as part of step S27 because of an infringement of the maximum permissible total energy consumption Emax Alternatively, it is possible that the maximum permissible total energy consumption Emax is prescribed externally—for example by the operator of the electrical supply network 5—or is varied by the control device 6 as a function of a network load N on the electrical supply network 5. In this case, the approach in FIG. 5 will be varied as shown in FIG. 14.

In FIG. 14, the steps S36 and S37 are inserted before step S1. In step S36, the control device 6 determines a network load N. The control device 6 can determine the network load N, for example, by reference to the time of day and/or year, or on the basis of a metrological detection of values from which the network load N can be deduced. In step S37, the control device 6 determines, by reference to the network load N, the maximum permissible energy consumption Emax.

In summary, the present invention thus relates to the following technical situation:

A basic materials industry facility has at least one electrical consumer 1, 2 of type 1. For each consumer 1, 2, of type 1, three working points Aij are defined, to each of which is assigned a power consumption PEij that is to be expected from a supply network 6. The basic materials industry facility can have further electrical consumers 3, 4 of a type 2 or 3, for each of which either exactly two working points Aij are defined, to each of which is assigned a power consumption PEij that is to be expected from a supply network 5, or one single power consumption PEi is assigned that is to be expected from the supply network 5. Taking into account technological criteria for the operation of the basic materials industry facility, schedule diagrams for the consumers 1 to 3 of type 1 and 2—i.e. the specification of their working points Aij as a function of time t—are defined, and are continuously updated taking into account the actual energy consumption E1, in such a way that the expected total energy consumption E between a predefined starting time point T1 and a predefined end time point T2 does not exceed a maximum permissible total energy consumption Emax.

The present invention has many advantages. In particular, the maximum permissible energy consumption Emax can be almost fully utilized, while nevertheless enabling an optimal or almost optimal operation of the basic materials industry facility to be achieved. The productivity of the basic materials industry facility can be optimized, in particular in that idle times are minimized. In many cases, it is also possible to minimize losses due to wasted heat.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A method of operation for a basic materials industry facility, which has multiple electrical consumers that receive power from a supply network, at least one of the consumers being a type 1 consumer and the other consumers being type 1 or type 2 or type 3 consumers, wherein multiple working points are defined for each type 1 and type 2 consumer, each consumer being expected to draw an given amount of power from the supply network at a respective working point, each type 1 consumer having three working points, each type 2 consumer having exactly two working points, each type 3 consumer having an average expected power to be drawn from the supply network, said method comprising:
defining a schedule diagram for each type 1 and type 2 consumer, before a predefined starting time point, the schedule diagram that defines the relevant working point for the consumer for each time point within a time window extending at least from a starting time point to a predefined first end time point, taking into account technological criteria for the operation of the basic materials industry facility, the schedule diagrams providing an initial expected total energy consumption that does not exceed a maximum permissible total energy consumption;
determining for each actual time point between the starting time point and the first end time point, an instantaneous expected total energy consumption, the expected total energy consumption at each instant being given by the sum of the electrical energy actually drawn from the supply network by the consumers from the starting time point up to the relevant actual time point, the instantaneous expected total energy consumption being determined using measurement data;
determining an expected remaining energy consumption for the period from the relevant actual time point up to the first end time point, the relevant expected remaining energy consumption being given by the schedule diagrams for the type 1 and type 2 consumers from the relevant actual time point up to the first end time point, and the average amounts of power that are expected to be drawn from the supply network by the type 3 consumers,
comparing the expected total energy consumption to the maximum permissible total energy consumption; and
varying the schedule diagram for at least one type 1 or type 2 consumer and/or switching off, or inhibiting the switching-on of at least one type 3 consumer when an expected total energy consumption exceeds the maximum permissible total energy consumption, taking into account the technological criteria for the operation of the basic materials industry facility, so that the expected total energy consumption does not exceed the maximum permissible total energy consumption.

2. The method of operation of claim 1, further comprising:
comparing the relevant expected total energy consumption to a minimum total energy consumption; and
when the relevant expected total energy consumption falls below the minimum total energy consumption varying the schedule diagram for at least one type 1 or type 2 consumer by switching on at least one of the type 1 or type 2 consumer, taking into account the technological criteria for the operation of the basic materials industry facility, and/or switching on at least one of the type 3 consumers, so that the expected total energy consumption is brought close to the maximum permissible energy consumption.

3. The method of operation of claim 1, wherein the schedule diagrams extend at least as far a second end time point beyond the first end time point, and further comprising taking into account a further expected energy consumption relating to a time period between the first end time point and the second end time point, the time difference between the second end time point and the first end time point being equal to the time difference between the first end time point and the starting time point, in determining or varying the schedule diagrams.

4. The method of operation of claim 1 wherein the energy actually consumed between the starting time point and the first end time point exceeds the maximum permissible total energy consumption, and further comprising increasing the maximum permissible total energy consumption for at least one time period following the first end time point.

5. The method of operation of claim 1, further comprising assigning a priority level to each of the consumers of type 1 and of type 2, statically or dynamically, so that when schedule diagrams are varied, preference is given to varying the schedule diagrams of the consumers of type 1 and type 2 having a low in priority level at that instant.

6. The method of operation of claim 1, further comprising:
detecting the amounts of power actually drawn from the supply network by the type 1 and of type 2 consumers; and
updating an amount of power that is expected to be drawn from the supply network that is assigned to a working point of one of the consumers, using the amounts of power actually drawn from the supply network.

7. The method of operation of claim 1, further comprising:
detecting the amounts of power actually drawn from the supply network by consumers of type 3; and
updating the amounts of power assigned to consumers of type 3 that are expected to be drawn from the supply network, using the amounts of power actually drawn from the supply network by the consumers of type 3.

8. The method of operation of claim 1, wherein the basic materials industry facility is electric steel works that has as electrical consumers of type 1, including an arc furnace and/or a hearth oven that has electrodes that are fed from the supply network and have a working point that includes a setting for the height of the electrodes above a surface of the bath of the arc furnace or hearth oven, and further comprising adjusting the height of electrodes above a surface of the bath in an arc furnace or hearth oven.

9. The method of operation of claim 1, further comprising varying the maximum permissible total energy consumption as a function of the network load on the electrical supply network.

10. A computer program adapted to be executed in a basic materials industry facility having multiple electrical consumers that receive power from a supply network, at least one of the consumers being a type 1 consumer and the other consumers being type 1 or type 2 or type 3 consumers, wherein multiple working points are defined for each type 1 and type 2 consumer, each consumer being expected to draw a given amount of power from the supply network at a respective working point, each type 1 consumer having three working points, each type 2 consumer having exactly two working points, each type 3 consumer having an average expected power to be drawn from the supply network for operating basic materials industry facility, said computer program comprising:
computer code for defining a schedule diagram for each type 1 and type 2 consumer before a predefined starting time point, said schedule diagrams defining the relevant working point for a respective consumer for each time point within a time window extending at least from the starting time point to a predefined first end time point, said schedule diagram taking into account technological criteria for the operation of the basic materials industry facility, said schedule diagrams providing an initial expected total energy consumption that does not exceed a maximum permissible total energy consumption;
computer code for determining for each actual time point between the starting time point and the first end time point, an instantaneous expected total energy consumption, the expected total energy consumption at each instant being given by the sum of the electrical energy actually drawn from the supply network by the consumers from the starting time point up to the relevant actual time point, said instantaneous expected total energy consumption being determined using measurement data;
computer code for determining an expected remaining energy consumption for the period from the relevant actual time point up to the first end time point, the relevant expected remaining energy consumption being given by the schedule diagrams for the consumers of type 1 and type 2 from the relevant actual time point up to the first end time point, and the average amounts of power that are expected to be drawn from the supply network by the consumers of type 3;
computer code for comparing the expected total energy consumption to the maximum permissible total energy consumption; and
computer code for varying the schedule diagram for at least one consumer of type 1 or type 2, and/or switching off or inhibiting the switching-on of at least one consumer of type 3 when the expected total energy consumption exceeds the maximum permissible total energy consumption, taking into account the technological criteria for the operation of the basic materials industry facility, so that the expected total energy consumption does not exceed the maximum permissible total energy consumption.

11. The computer program of claim 10, wherein at least part of the computer program is written machine code that can be executed by a control device in a basic materials industry facility.

12. A control device for controlling the operation of selected electrical consumers in a basic materials industry facility that receive power from a supply network, at least one of the consumers being a type 1 consumer and the other consumers being type 1 or type 2 or type 3 consumers,
computer code having multiple working points for each type 1 and type 2 consumer, each consumer being expected to draw an given amount of power from the supply network at a respective working point, each type 1 consumer having three working points, each type 2 consumer having two working points, and an average expected power to be drawn from the supply network for each type 3 consumer;
computer code for defining a schedule diagram for each of the selected type 1 and type 2 consumers before a predefined starting time point, said schedule diagrams defining the relevant working point for a respective consumer for each time point within a time window extending at least from the starting time point to a predefined first end time point, said schedule diagram taking into account technological criteria for the operation of the basic materials industry facility, said schedule diagrams providing an initial expected total energy consumption that does not exceed a maximum permissible total energy consumption;
computer code for determining for each actual time point between the starting time point and the first end time point, an instantaneous expected total energy consumption for the selected energy consumers, the expected total energy consumption at each instant being given by the sum of the electrical energy actually drawn from the supply network by the consumers from the starting time point up to the relevant actual time point, said instantaneous expected total energy consumption being determined using measurement data;
computer code for determining an expected remaining energy consumption for the period from the relevant actual time point up to the first end time point for the selected energy consumers, the relevant expected remaining energy consumption being given by the schedule diagrams for the consumers of type 1 and type 2 from the relevant actual time point up to the first end time point, and the average amounts of power that are expected to be drawn from the supply network by the consumers of type 3;
computer code for comparing the expected total energy consumption to the maximum permissible total energy consumption; and
computer code for varying the schedule diagram for at least one consumer of type 1 or type 2, and/or switching off or inhibiting the switching-on of at least one consumer of type 3 when the expected total energy consumption exceeds the maximum permissible total energy consumption, taking into account the technological criteria for the operation of the basic materials industry facility, so that the expected total energy consumption does not exceed the maximum permissible total energy consumption.

13. A basic materials industry facility, comprising:
multiple electrical consumers that receive power from a supply network, at least one of the consumers being a type 1 consumer and the other consumers being type 1 or type 2 or type 3 consumers;
a control network for operating the basic materials industry facility, said control network being adapted to execute:
computer code having multiple working points for each type 1 and type 2 consumer, each consumer being expected to draw an given amount of power from the supply network at a respective working point, each type 1 consumer having three working points, each type 2 consumer having two working points, and an average expected power to be drawn from the supply network for each type 3 consumer;
computer code for defining a schedule diagram for each of the selected type 1 and type 2 consumers before a predefined starting time point, said schedule diagrams defining the relevant working point for a respective consumer for each time point within a time window extending at least from the starting time point to a predefined first end time point, said schedule diagram taking into account technological criteria for the operation of the basic materials industry facility, said schedule diagrams providing an initial expected total energy consumption that does not exceed a maximum permissible total energy consumption;
computer code for determining for each actual time point between the starting time point and the first end time point, an instantaneous expected total energy consumption for the selected energy consumers, the expected total energy consumption at each instant being given by the sum of the electrical energy actually drawn from the supply network by the consumers from the starting time point up to the relevant actual time point, said instantaneous expected total energy consumption being determined using measurement data;
computer code for determining an expected remaining energy consumption for the period from the relevant actual time point up to the first end time point for the selected energy consumers, the relevant expected remaining energy consumption being given by the schedule diagrams for the consumers of type 1 and type 2 from the relevant actual time point up to the first end time point, and the average amounts of power that are expected to be drawn from the supply network by the consumers of type 3;
computer code for comparing the expected total energy consumption to the maximum permissible total energy consumption; and
computer code for varying the schedule diagram for at least one consumer of type 1 or type 2, and/or switching off or inhibiting the switching-on of at least one consumer of type 3 when the expected total energy consumption exceeds the maximum permissible total energy consumption, taking into account the technological criteria for the operation of the basic materials industry facility, so that the expected total energy consumption does not exceed the maximum permissible total energy consumption.

14. The basic materials industry facility of claim 13, wherein the basic materials industry facility is electric steel works and the type 1 electrical consumers include an arc furnace and/or a hearth oven.
